(19) United States
(12) Patent Application Publication
(10) Pub. No.: US 2025/0202473 A1
(43) Pub. Date: Jun. 19, 2025

(54) SOLID STATE SWITCH DEVICE

(71) Applicant: Analog Devices International Unlimited Company, Co. Limerick (IE)

(72) Inventors: Jofrey Santillan, Limerick (IE); Declan McDonagh, Limerick (IE); David Aherne, Limerick (IE)

(73) Assignee: Analog Devices International Unlimited Company, Co. Limerick (IE)

(21) Appl. No.: 18/524,777

(22) PCT Filed: Jan. 25, 2023
(86) PCT No.: PCT/EP2023/051786

§ 371 Date: Nov. 30, 2023

(51) Int. Cl. H03K 17/16; H03K 17/14

(52) U.S. Cl. CPC H03K 17/162; H03K 17/145; H03K 2217/0027

(57) ABSTRACT

A new MOS based switch for use in/with high voltage precision instruments is provided. The switch can enable leakage compensation. The switch can comprise a MOS device and a compensation circuit coupled to the MOS device to replicate and compensate for the MOS device leakage, such that the switch appears not to leak current. The compensation circuit may comprise a sense device which acts as a scaled replica of the MOS device being compensated. The sense device's leakage current can then be measured, reproduced at the scale factor, and injected back to the drain terminal of the MOS device.

### CROSS REFERENCE TO RELATED PATENT APPLICATIONS

The present application is a U.S. 371 National Stage of PCT Patent Application No. PCT/EP2023/051786, entitled “A SOLID STATE SWITCH DEVICE”, naming as inventors, Jofrey Santillan, Declan McDonagh, and David Aherne, and filed Jan. 25, 2023, which application is hereby incorporated by reference in its entirety.

### FIELD

This application relates to compensating for leakage in a semiconductor switch (i.e. a solid state switch device). Specifically, a metal-oxide-semiconductor field-effect-transistor (MOSFET or MOS), e.g., a high voltage MOS, such as a diffusion metal oxide semiconductor field effect transistor (DMOS).

### BACKGROUND

Solid state switch devices may be used with components such as, a precision measurement apparatus, and high voltage automated test equipment. A solid state switch device can have an associated leakage which affects the results at a precision measurement apparatus. For example, a large leakage current can reduce power efficiency and reduces the accuracy of component measurements connected via a solid state switch device. Leakage compensation herein refers to the process of measuring a leakage, creating a copy and then using the copy to cancel the original leakage.

### SUMMARY OF THE DISCLOSURE

The present disclosure provides a solid state switch device which compensates for current leakage. In particular, the examples herein provide leakage compensation techniques which are suitable with non-isolated and fully isolated (e.g., a silicon-on-insulator (SOI), or buried oxide isolated device) switches. In addition, the examples herein also provide an area efficient implementation. Such solid state switch devices are suitable for use with AC voltage precision measurement apparatuses and AC high voltage automated test equipment.

According to a first aspect there is provided a solid state switch device, comprising:
a switch component comprising a metal-oxide-semiconductor field-effect transistor, MOSFET, comprising a drain terminal, a source terminal, a gate terminal, and configured to generate a switch component leakage current based on non-idealities of the MOSFET;
a compensation circuit comprising:
a sense device for compensating current leakage of the switch component, and configured to generate a sense device leakage current that is correlated with the switch component leakage current; and
a current amplifier configured to:
   generate an estimated switch component leakage current (˜i₁) based on the sense device leakage current (i₂);
   output the estimated switch component leakage current to the drain terminal of the MOSFET in order to compensate for the switch component leakage current.

Optionally, the compensation circuit is configured to detect a voltage level at the drain terminal of the MOSFET. Optionally, the compensation circuit is configured to apply the voltage level to the sense device in order to generate the sense device leakage current correlated with the switch component leakage current.

Optionally, the MOSFET is a first LDMOS, and the switch component further comprises a second LDMOS comprising: a drain terminal, a source terminal, a gate terminal, wherein the source terminal of the second LDMOS is coupled to the source terminal of the first LDMOS.

Optionally, the estimated switch component leakage current is a multiple of the sense device leakage current.

Optionally, the sense device leakage current is correlated with the switch component leakage current such that the sense device leakage current is N times less than the switch component leakage current. Optionally, the multiple is N.

Optionally, the MOSFET is a buried oxide isolated device, and the switch component further comprises an electrostatic discharge (ESD) diode. Optionally, the switch component leakage current is further based on non-idealities of the ESD diode.

Optionally, the current amplifier is a current mirror comprising: a first transistor device coupled to the sense device; and a second transistor device coupled to the drain terminal of the MOSFET of the switch component. Optionally, the second transistor device has a first scale greater than a second scale of the first transistor device.

Optionally, the second transistor device comprises more transistors than the first transistor device.

Optionally, the current amplifier comprises an operational amplifier comprising a first output and a second output. Optionally, the first output sources a first current. Optionally, the second output sources a second current. Optionally, the second current is a multiple of the first current. Optionally, the first output is coupled to the sense device. Optionally, the second output is coupled to the drain terminal of the MOSFET of the switch component.

Optionally, the switch component is a first switch component, the MOSFET is a first MOSFET, and the sense device is a second switch component. Optionally, the second switch component comprises a second MOSFET comprising: a drain terminal, a source terminal, a gate terminal. Optionally, the sense device leakage current is based on non-idealities of the second MOSFET. Optionally, the first MOSFET has a first scale greater than a second scale of the second MOSFET.

Optionally, the sense device comprises a cathode coupled to the current amplifier and an anode coupled to the voltage source supply (Vss).

Optionally, the sense device is coupled to the voltage source supply, Vss, via a switch. Optionally, the switch is configured to be open when the switch component is closed.

Optionally, the solid state switch device of the first aspect further comprises a temperature sensor configured to activate the compensation circuit upon sensing a temperature above a temperature threshold.

According to a second aspect there is provided a compensation circuit comprising:
a sense device for leakage compensation of a switch component leakage current of a switch component, and configured to generate a sense device leakage current; and
a current amplifier configured to:
generate an estimated switch component leakage current (˜i₁) based on the sense device leakage current (i₂);
output the estimated switch component leakage current to the switch component in order to compensate for the switch component leakage current.

Optionally, the estimated switch component leakage current is a multiple of the sense device leakage current.

Optionally the switch component leakage current is greater than the sense device leakage current.

The buffer may be a unity gain buffer, a voltage follower, or a cascade complementary source follower.

The MOSFET of the switch component may be a high voltage MOSFET, and the MOSFET of the sense device may be an 5V MOSFET.

The MOSFET of the switch component may be a Diffusion MOSFET (DMOS).

The MOSFET of the switch component may be a first DMOS. The switch component may further comprise a bi-directional DMOS switch comprising the first DMOS and a second DMOS. The second DMOS may comprise a gate terminal, a drain terminal, and a source terminal. The source terminal of the second DMOS may be coupled to the source terminal of the first DMOS.

The bi-directional DMOS switch may be a bi-directional Lateral Double-Diffusion MOSFET (LDMOS) switch. The first DMOS transistor may be an LDMOS and the second DMOS transistor may be an LDMOS.

According to a third aspect there is provided a method of compensating for a switch component leakage current of a switch component, the method comprising:
determining a voltage level at an output of the switch component;
applying the voltage level to a sense device;
determining a sense device leakage current of the sense device that is correlated with the switch component leakage current;
generating an estimated switch component leakage current (˜i₁) based on the sense device leakage current;
outputting the estimated switch component leakage current to the output of the switch component in order to compensate for the switch component leakage current.

Optionally, the estimated switch component leakage current is a multiple of the sense device leakage current.

According to a fourth aspect there is provided a method of compensating for a switch component leakage current of a switch component:
sensing an activation temperature above a temperature threshold; and
providing the method of the second aspect, in response to sensing the activation temperature.

According to a fifth aspect there is provided a solid state switch device, comprising:
a silicon-on-insulator (SOI) switch component comprising a first metal-oxide-semiconductor field-effect transistor, MOSFET, and a second MOSFET, each MOSFET comprising a drain terminal, a source terminal, a gate terminal, wherein the source terminal of the first MOSFET is coupled to the source terminal of the second MOSFET defining a mid-point;
a compensation circuit comprising:
   a sense device coupled to the mid-point and arranged to pass a leakage current to a reference node; and
   a current mirror arrangement configured to:
      replicate the leakage current;
generate and provide a first compensation current to the drain terminal of the first MOSFET; and
generate and provide a second compensation current to the drain terminal of the second MOSFET.

Optionally, the first compensation current and the second compensation current are each approximately half of the leakage current.

Optionally, the solid state switch device of the fifth aspect further comprises a temperature sensor configured to activate the compensation circuit upon sensing a temperature above a temperature threshold.

### FIGURES

FIG. 1 illustrates a design of a NLDMOS switch.

FIG. 2 illustrates a bi-directional NLDMOS switch comprising a first NLDMOS and a second NLDMOS in series.

FIG. 3a illustrates the LDNMOS of FIGS. 1 and 2 with a parasitic drain-substrate capacitor (C_{dsub}) shown.

FIG. 3b illustrates the LDNMOS of FIGS. 1 and 2 with the parasitic drain-substrate capacitor (C_{dsub}), a parasitic source-drain capacitor (C_{sd}), a parasitic gate-source capacitor (C_{gs}), and a parasitic gate-drain capacitor (C_{gd}).

FIG. 4 illustrates an example of a semiconductor structure of an LDMOS transistor, specifically an NLDMOS.

FIG. 5 illustrates a block diagram of a solid state switch device comprising switch component (such as an NLDMOS switch if FIG. 1 or a bi-directional NLDMOS switch of FIG. 2) and a compensation circuit.

FIG. 6 illustrates an implementation of the block diagram of the solid state switch device of FIG. 5.

FIG. 7 illustrates an implementation of the block diagram of the solid state switch device of FIG. 5.

FIG. 8 illustrates an implementation of the block diagram of the solid state switch device of FIG. 5.

FIG. 9 illustrates an implementation of the block diagram of the solid state switch device of FIG. 5.

FIG. 10 illustrates an implementation of the block diagram of the solid state switch device of FIG. 5, with a SOI switch component.

FIG. 11 illustrates an implementation of the block diagram of the solid state switch device of FIG. 5, with a SOI switch component.

FIG. 12 illustrates an implementation of the block diagram of the solid state switch device of FIG. 5.

FIG. 13 illustrates an implementation a solid state switch device with a SOI switch component.

FIG. 14 illustrates a block diagram of a solid state switch device of FIG. 5 further comprising a temperature sensor.

FIG. 15 illustrates a flow diagram of a method of operating the device of FIGS. 5 and 14.

### DETAILED DESCRIPTION

A metal-oxide-semiconductor field-effect-transistor (MOSFET or MOS) device when configured to function as a switch is susceptible to parasitic capacitance and current leakage which can negatively impact measurement performance of equipment connected via said MOS device. To overcome the impact of parasitic capacitance and current leakage, additional circuitry can be coupled to the MOS device configured to function as a switch. All types of MOS devices (e.g., Diffusion MOSs (DMOSs), Lateral DMOSS (LDMOSs), vertical DMOSs (VDMOSs), etc.) can benefit from the additional circuitry. For example, the MOS devices described below are LDMOS devices configured to function as switches. In addition, the LDMOS devices may be lateral doubly diffused MOS devices. A DMOS device may imply a high-voltage device. For example, greater than 5V, or, greater than/equal to 10V, can be high-voltage.

As a brief non-limiting overview of the invention, a new MOS based switch for use in/with high voltage precision instruments is provided. The switch can enable leakage compensation. The switch can comprise a MOS device and a compensation circuit coupled to the MOS device to replicate and compensate for the MOS device leakage, such that the switch appears not to leak current. The compensation circuit may comprise a sense device which acts as a scaled replica of the MOS device being compensated. The sense device's leakage current can then be measured, reproduced at the scale factor, and injected back to the drain terminal of the MOS device.

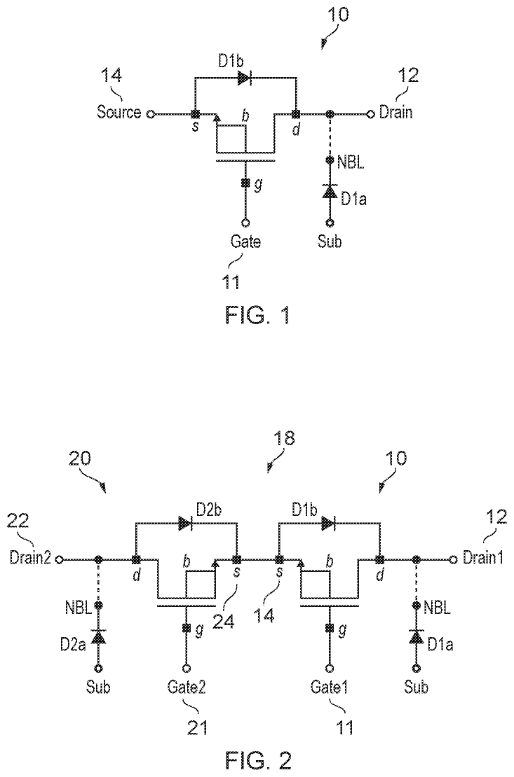

FIG. 1 shows an n-type LDMOS 10 (i.e., NLDMOS 10) with its parasitic diodes D1a and D1b. The parasitic diodes D1a and Db of the NLDMOS 10 result from the fabrication process and are present in many types of DMOS switches. D1a may not be present in silicon-on-insulator (SOI) DMOS switches. The parasitic diode D1a (between the substrate and an isolation layer, e.g. an N-type buried layer (NBL)) of the NLDMOS 10 is also present in MOSFET switches.

NLDMOS 10 comprises a gate terminal 11, a drain terminal 12, and a source terminal 14. D1a is formed between the substrate and the isolation layer, such as an NBL in FIG. 1. The NBL is coupled to a NBL terminal, which may be accessible to a circuit designer. The NBL terminal may typically be shorted to the drain terminal 12 for normal operation, which may reduce noise from the substrate. This may be achieved by externally coupling the NBL terminal to the drain terminal 12 or may be achieved by an internal connection of the NBL to the drain. D1b is formed between the source (via a backgate shorted to the source) and drain of the NLDMOS 10. The parasitic diodes D1a and D1b are formed between P-type and N-type material of the NLDMOS 10.

A P-type LDMOS (PLDMOS) (or other p-type MOS switch) could be described similarly.

LDMOS devices are suitable for use in high voltage applications and may have region(s) (e.g., typically the drain region) formed using a double diffusion process. As a result of the fabrication process, the NLDMOS 10 is a uni-directional solid state switch device and the parasitic diodes D1a and D1b are formed between high voltage P-type and N-type material. For example, when gate terminal 11 of the (uni-directional) NLDMOS switch 10 receives an ‘OFF’ signal, current may still flow from source terminal 14 to drain terminal 12 via the (forward biased) parasitic diode D1b.

FIG. 2 shows a bi-directional NLDMOS switch 18 comprising a first NLDMOS 10 and a second NLDMOS 20 in series. The second NLDMOS 20 comprises a gate terminal 21, a drain terminal 22, and a source terminal 24. The second NLDMOS 20 can be identical to the first NLDMOS 10. The source terminal 14 of the first NLDMOS 10 is coupled to a source terminal 24 of the second NLDMOS 20. The bi-directional NLDMOS switch 18 is arranged to, when ‘OFF’, block current flow in both directions: from the drain terminal 22 of the second NLDMOS 20 to the drain terminal 12 of the first NLDMOS 10; and from the drain terminal 12 of the first NLDMOS 10 to the drain terminal 22 of the second NLDMOS 20. To turn the first and second LDMOSs 10, 20 ‘OFF’, the gate-source voltage (Vgs) (between the gate terminals 11, 21 of the first and second LDMOSs 10, 20 and the source terminals 14, 24) is less than the threshold voltage (Vt), e.g., Vss. For example, the first and second LDMOSs 10, 20 may be turned ‘OFF’ by coupling gate terminals 11, 21 to source terminals 14, 24, or, by coupling both gate terminals 11, 21 and source terminals 14, 24 to the substrate (e.g., Vss).

If the voltage at the drain terminal 22 of the second NLDMOS 20 is greater than the voltage at the drain terminal 12 of the first NLDMOS 10, when both of the first and second NLDMOSs 10, 20 are ‘ON’, then the first and second NLDMOSs 10, 20 can allow current to flow from the drain terminal 22 of the second NLDMOS 20 to the drain terminal 12 of the first NLDMOS 12. When both of the first and second NLDMOSs 10, 20 are ‘OFF’, the second NLDMOS 20 blocks current flow from the drain terminal 22 to the source terminal 24 of the second NLDMOS 20 because the channel of the second NLDMOS 20 is pinched off and a parasitic diode D2b of the second NLDMOS 20 is reverse biased.

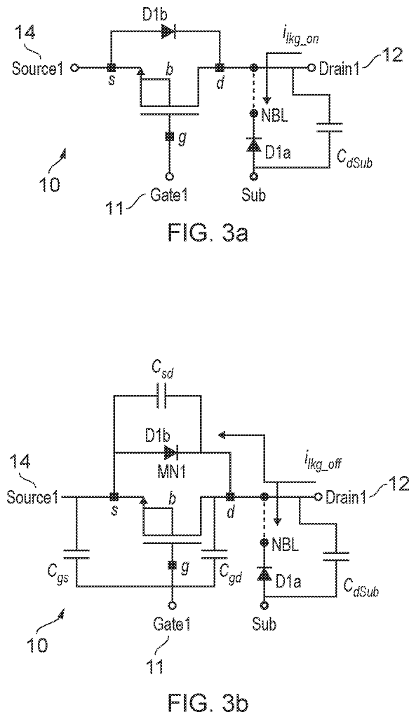

FIGS. 3a and 3b show the NLDMOS 10 of FIGS. 1 and 2 configured to generate a leakage current based on non-idealities of the NLDMOS 10.

FIG. 3a shows the NLDMOS 10 of FIGS. 1 and 2 with a parasitic drain-substrate capacitor (C_{dsub}) shown. Alternatively, the NLDMOS 10 may be any type of MOS. The parasitic components shown in FIG. 3a are the dominant parasitic components when the NLDMOS 10 is switched ‘ON’.

When the NLDMOS 10 is in the on-state the drain/source voltage can be any value usually between the power supplies (e.g., Vcc and Vee). If the NLDMOS 10 is switched ‘ON’, the voltage difference between the source terminal 14 and the drain terminal 12 is approximately 0V (assuming a negligible/low ON-resistance). There can be a large voltage differential across the parasitic diode D1a and the C_{dsub} as the substrate may be connected to 0V or the most negative supply (e.g., Vss). The large voltage differential across the parasitic diode D1a causes: a leakage current i_{lkg_on} through the reverse biased parasitic diode D1a; and the associated C_{dsub}. The leakage current i_{lkg_on} reduces power efficiency and reduces the accuracy of component measurements connected via the NLDMOS 10. The C_{dsub} reduces the accuracy of component measurements connected via the NLDMOS 10.

FIG. 3b shows the NLDMOS 10 of FIGS. 1 and 2 with the parasitic drain-substrate capacitor (C_{dsub}), a parasitic source-drain capacitor (C_{sd}), a parasitic gate-source capacitor (C_{gs}), and a parasitic gate-drain capacitor (C_{gd}). The parasitic components shown in FIG. 3b are the dominant parasitic components when the NLDMOS 10 is switched ‘OFF’ and the voltage at the drain 12 is greater than the voltage at the source 14.

If the NLDMOS 10 is switched ‘OFF’ and the voltage at the drain 12 is greater than the voltage at the source 14, then there is a large voltage differential across the parasitic diode D1a, the C_{dsub}, the parasitic diode D1b, the C_{sd}, the C_{gd} and potentially C_{gs} (depending on the voltage difference between the gate 11 and the source 14). The large voltage differential across the parasitic diodes D1a and D1b causes: a leakage current i_{lkg_off} through the reverse biased parasitic diodes D1a and D1b; and the C_{dsub}, the C_{sd}, the C_{gd}, and potentially the C_{gs}. The leakage current i_{lkg_off} reduces power efficiency and reduces the accuracy of component measurements connected via the NLDMOS 10.

The C_{dsub}, the C_{sd}, the C_{gd}, and potentially the C_{gs}, reduce the accuracy of component measurements connected via the NLDMOS 10. For example, a low capacitance is suitable for (high-voltage) AC voltage applications such as data acquisition systems (e.g., ADAQ7768-1). Such systems may preferably work at higher input frequencies with good total harmonic distortion (THD).

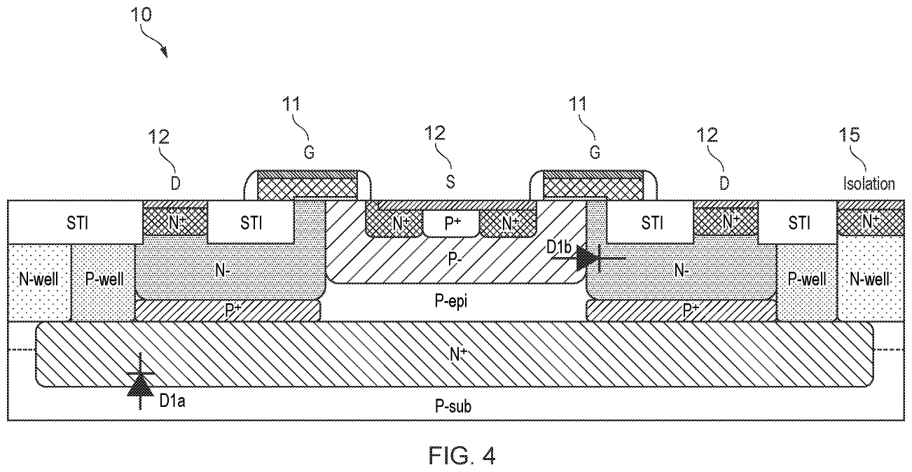

FIG. 4 shows an example of a semiconductor structure of an NLDMOS transistor, specifically an NLDMOS 10. The parasitic diodes D1a and D1b are shown in FIG. 4.

As shown in FIGS. 3a, 3b, and 4 the NLDMOS 10 is susceptible to leakage currents and capacitances which reduce the accuracy of component measurements connected via the NLDMOS 10, can limit the speed of high frequency AC components connected via the solid state switch device, and reduce the power efficiency of the NLDMOS 10.

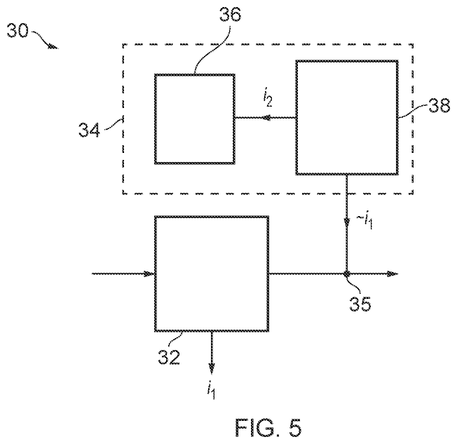

FIG. 5 shows a solid state switch device 30 comprising a switch component 32, and a compensation circuit 34. The switch component 32 is configured to generate a switch component leakage current based on the non-idealities of components of the switch component 32.

To compensate for leakage at a node 35 of the switch component 32, a possible solution is to create a copy of the leakage components on-chip (i.e., the sense device 32) to generate a replica leakage current and then apply the replica leakage current to the node 35 of the switch component 32. However, this solution may at least double the area required for a solid state switch device. To increase area efficiency, the switch component has a first scale greater than a second scale of the sense device. That is the sense device 36 may be scaled down by a scale factor N (e.g., N=100) when compared to the switch component. Therefore, the replica leakage current is N times less than the leakage current of the switch component 32. Then the replica leakage current in the sense device 36 will need to be amplified by the scale factor N (e.g., 100 times) to produce the correct leakage for the switch component 32.

Scaling may refer to linear scaling, for example each shown “MOS device” 10, 20 (of FIG. 2) of the switch component 32 may be made of 200 MOS devices [in silicon] and each shown “MOS device” of the sense device 36 may be made of 2 MOS devices [in silicon] to generate a linear scaling of 100:1. Alternatively, any other scale factor N is possible depending on the application of the solid state switch device. Scaling may also refer to non-linear scaling, for example each MOS device of the sense device 34 may be 100 times smaller in size than each MOS device 10, 20 switch component 32.

The switch component 32 can comprise any MOS device shown in FIGS. 1 to 4. Therefore, the switch component leakage current i₁ may be based on the non-idealities of a MOSFET, such as, parasitic diodes and capacitances of the first NLDMOS 10. In particular, the switch component 32 may be a non-isolated or a fully isolated (e.g., a silicon-on-insulator (SOI), or buried oxide isolated device) switch because the sense device 34 may be arranged in many ways (at least such as those disclosed herein) to compensate for the leakage due to any parasitics of the switch component 32 (or an electrostatic discharge (ESD) diode associated with the switch component 32).

The compensation circuit 34 comprises a sense device 36 and a current amplifier 38. The sense device 34 can comprise any MOS device shown in FIGS. 1 to 4. The sense device is configured to generate a sense device leakage current i₂ which may be based on the non-idealities of the sense device 36. Therefore, the sense device leakage current may be based on the non-idealities of a MOSFET, such as, parasitic diodes and capacitances of the first NLDMOS 10.

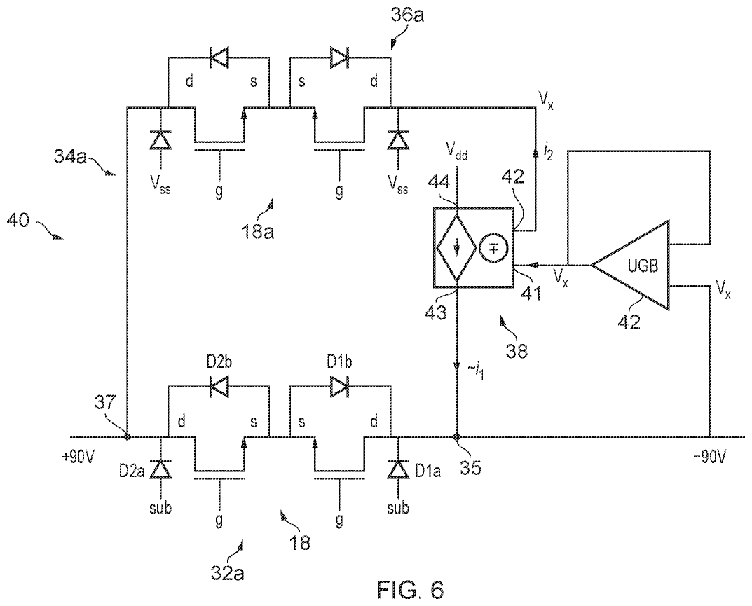

The sense device 36 is for leakage compensation of the switch component 32 and, in use, has a sense device leakage current i₂. Due to the arrangement of the sense device 36, the sense device 36 generates a sense device leakage current i₂ correlated with the switch component leakage current i₁. For example, the switch component leakage current i₁ may be N times greater than the sense device leakage current i₂, when a corresponding voltage is applied to each terminal of the switch component 32 and the sense device 36. The current amplifier 38 is configured to generate an estimated switch component leakage current ˜i₁ with the aim to cancel the switch component leakage current i₁. The estimated switch component leakage current ˜i₁ is based on the sense device leakage current i₂, such that the estimated switch component leakage current ˜i₁ may be a multiple of the sense device leakage current. The estimated switch component leakage current ˜i₁ is output to the node 35 of the switch component 32 (i.e., the drain terminal of the MOSFET) in order to compensate for the switch component leakage current i₁. Parasitic components of the switch component 32 and the sense device 36 are not shown in FIG. 5 for clarity purposes, however, at least the main relevant parasitic components of the switch component 32 can be seen in FIGS. 6 to 13.

The estimated switch component leakage current ˜i₁ may be within 50%, 60%, 70%, 80%, 90%, 95%, 98%, 99%, or 99.5% of the switch component leakage current i₁.

FIG. 6 shows a solid state switch device 40 which is an example of the solid state switch device 30 of FIG. 5. The switch component 32a is a bi-directional NLDMOS switch 18, as shown in FIG. 2. The switch component 32a has a switch component leakage current defined by parasitic diodes D1a, D1b, D2a, D2b. A compensation circuit 34a comprises a current amplifier 38, a unitary gain buffer (UGB) 42, and a sense device 36a. The sense device 36a is a scaled (e.g., linearly or non-linearly scaled) version of the switch component 32a. The sense device 36a comprises a bi-directional NLDMOS switch 18 which is N times smaller than the switch component 32a. Thus, the sense device 36a has a scale factor of N.

The compensation circuit 34 is configured to detect a voltage level Vx at the drain terminal of the MOSFET of the switch component. The compensation circuit 34a is further configured to apply a voltage at the voltage level Vx to the sense device in order to generate a sense device leakage current. The sense device leakage current is correlated with the switch component leakage current because both are voltage level Vx dependent, which allows an improved estimate of the switch component leakage current i₁.

Leakage compensation is desired on a node 35, thus the node 35 is provided to an input of the UGB 42. The UGB 42 has a high impedance input and does not draw current from the node 35. The output of the UGB 42 is coupled to a first input 41 of the current amplifier 38 (arranged as a current controlled current source), and a first output 42 of the current amplifier is applied to a first drain terminal of the sense device 36a. A second drain terminal of the sense device 36a is coupled to the second drain terminal of the switch component 32a (i.e., node 37). The UGB 42 is arranged to source current, therefore, current drawn by the sense device 36a is ideally equal to the leakage current i₂ of the sense device 36a. Since the sense device 36a is an N-scaled version of the switch component 32a, the sense device 36a results in N-times less leakage current than the switch component 32a. As the leakage current i₂ is drawn from the UGB 42 it is passed through the current amplifier 38 and is multiplied by the current amplifier 38 by the scale factor of the sense device 36a (i.e., N) to generate a compensation current ˜i₁. Therefore, a second output 43 of the current amplifier 38 (i.e., the compensation current) is approximately equal to the leakage current i₁ of the switch component 32a. A second input 44 of the current amplifier 38 is Vdd or another power supply.

Alternatively, in order to provide bi-directional compensation, a second compensation circuit similar to the compensation circuit 34a may be provided to provide an output (e.g., a compensation current approximately equal to a leakage current of the switch component 32a) coupled to a node 37 coupled to the second drain of the switch component 32a.

Alternatively, in order to provide bi-directional compensation, it is not necessary to replicate the sense device 36a in a second compensation circuit. Instead, the second drain terminal of the sense device 36a may be coupled to a first output of a second current amplifier (similar to current amplifier 38) and the first input of the second current amplifier may be coupled to an output of a second UGB. The second UGB being arranged to receive a voltage input at a node 37 coupled to the second drain of the switch component 32a. Therefore, the second current amplifier may generate a compensation current and apply it to the node 37 and the first current amplifier 38 may generate a compensation current and apply it to the node 35.

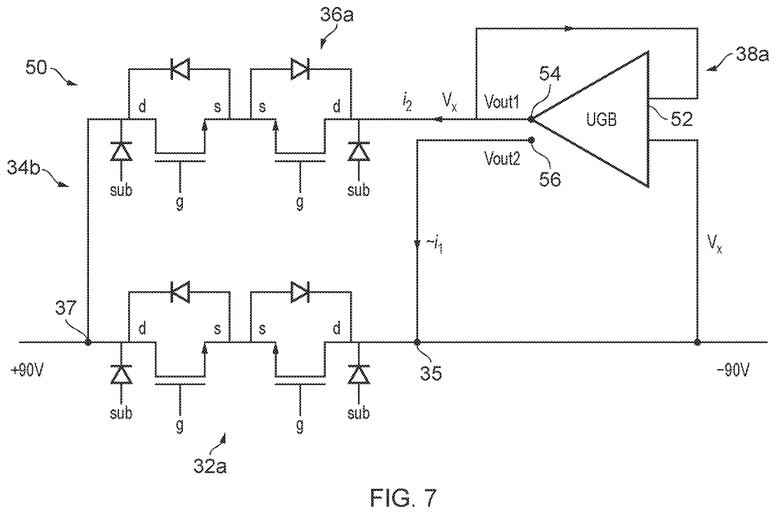

FIG. 7 shows a solid state switch device 50 which is an example of the solid state switch device 30 of FIG. 5. Some of the components in FIG. 7 are similar to components in FIG. 6 and use the same reference numbers. For purposes of conciseness, similar components will not be described in detail again. The current amplifier 38a of the compensation circuit 34 may be an operational amplifier (op-amp) 52 as shown in FIG. 7. The op-amp 52 has two output stages: a first output 54 and a second output 56. The first output 54 sources a first current i₂, and the second output 56 sources a compensation current ˜i₁. The first output 54 is coupled to the sense device 36a. The second output 56 is coupled to the drain terminal of the switch component 32a. The op-amp 52 is in a unity gain configuration. The op-amp 52 is arranged such that the current compensation ˜i₁ at the second output 56 is a multiple N of the first current i₂ at the first output 54.

In operation, corresponding voltages are applied to each terminal of the switch component 32a and the sense device 36a due to the op-amp 52 being configured to generate a unity gain. The switch component leakage current i₁ will be N times greater than the sense device leakage current i₂ due to the switch component 32a being N times the scale of the sense device 36a. Since the op-amp 52 can operate as a current source, the sense device 36a draws the sense device leakage current i₂ from the first output 54, therefore, the second output 56 generates a compensation current ˜i₁. The compensation current ˜i₁ is N times the sense device leakage current i₂ because the op-amp 52 controls the output current ratio N:1 (second output 56 current:first output 54 current). The op-amp 52 may comprise a cascode output stage which may provide current ratio stability over a large temperature range. The example of FIG. 7 may have an N equal to 20.

The voltage at an input node 37 of the solid state switch device 50 may be 90V, and the voltage at the output node 35 of the solid state switch device 50 may be −90V. The op-amp 52 may be a 5V op-amp. A 5V op-amp is possible with a power supply generator circuit. The power supply generator circuit may power the 5V op-amp for Vcc (90V) and Vss (−90V), and may track the voltage on the input node 37.

Alternatively, the op-amp 52 may be a 200V op-amp. A 200V op-amp would not require additional circuitry and may be more suitable for high frequency applications.

Alternatively, in order to provide bi-directional compensation, the second drain terminal of the sense device 36a may be coupled to a first output of a second op-amp (similar to op-amp 52), and the first input of the second op-amp may be arranged to receive a voltage input at the node 37. Therefore, the second op-amp 52 may generate a compensation current and apply it to the node 37.

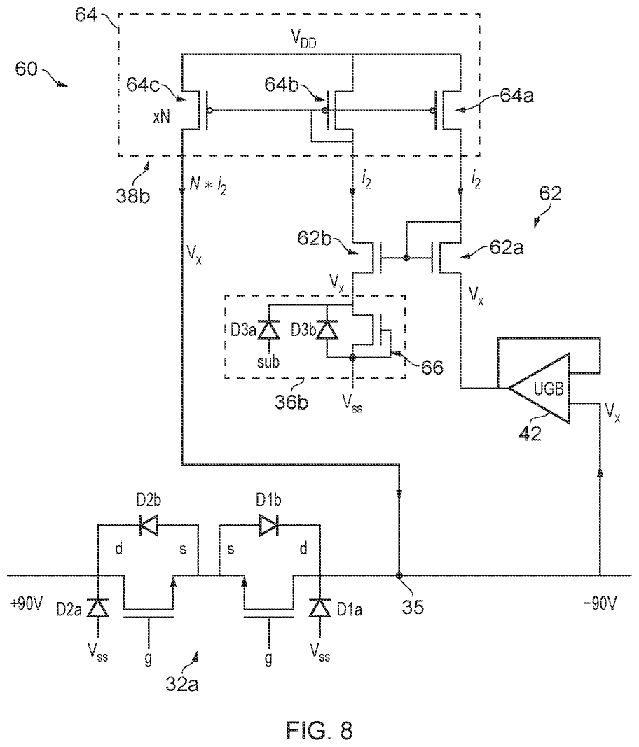

FIG. 8 shows a solid state switch device 60 which is an example of the solid state switch device 30 of FIG. 5. Some of the components in FIG. 8 are similar to components in FIG. 6 and use the same reference numbers. For purposes of conciseness, similar components will not be described in detail again. In contrast to the solid state switch device 40, solid state switch device 60 shows an alternative sense device 34 and an implementation of a current amplifier 38b.

The current amplifier 38b may be implemented as shown in solid state switch device 60 by a current mirror 64 comprising: a first transistor device 64b coupled to the sense device; and a second transistor device 64c coupled to the drain terminal of the MOSFET of the switch component, wherein the second transistor device has a first scale greater than a second scale of the first transistor device. Optionally, the current mirror 64 may further comprise a third transistor device 64a to match the on-resistance of the first transistor device 64b and to reduce the difference in current between the current path leading to the UGB 42 and the current path leading to the sense device 36b.

The current mirror 64 may be part of a current mirror arrangement. The output of the UGB 42 is coupled to the current mirror arrangement. The current mirror arrangement comprises two current mirror circuits: a first current mirror circuit 62 to apply the voltage Vx at the drain terminal of the switch component 32a to the sense device 36b; and a second current mirror circuit 64 to generate a compensation current based on the current drawn by the sense device 36b, and apply the compensation current to the node 35 coupled to the first drain of the switch component 32a. Optionally additional transistor devices may be added as protection devices. For example, each transistor device of the second current mirror 64 may comprise: a corresponding transistor device in series; and a gate coupled to a fixed voltage reference voltage below Vdd.

In operation a voltage Vx is applied at the output of the UGB 42 which corresponds to the voltage at node 35 coupled to the first drain of the switch component 32a. As a consequence, the first current mirror 62 applies the voltage Vx over the sense device 36b which then draws a leakage current i₂ (which is also drawn by the UGB 42 output due to the first current mirror 62). The amplification of the leakage current i₂ of the sense device 36b is achieved by the second current mirror 64, and specifically by scaling the transistor device 64c (directly coupled to the node 35 coupled to the first drain of the switch component 32a) by a scale factor ratio of N:1 in comparison to the other transistor devices 64a, 64b of the second current mirror 64. Therefore, the N-scaled transistor device 64c generates a compensation current ˜i₁ to the node 35 (=N*i₂).

The solid state switch device 60 also shows an implementation of a sense device 36b which is an alternative to a scaled replica of the MOS device being compensated as shown in FIGS. 6 and 7. The sense device 36b is a sense MOS device 66. The sense MOS device 66 has: a drain terminal coupled to the first current mirror 62 of the current mirror arrangement; a source terminal coupled to Vss (or other reference voltage/reference node); and a gate terminal coupled to the source terminal. That is, the sense MOS device 66 is arranged to always be in an off-state. Thus, the sense MOS device 66 comprises a cathode coupled to the current amplifier 38b and an anode coupled to the voltage source supply (Vss). The sense MOS device 66 is arranged to be N times smaller than a MOS device (e.g., LDMOS 10) of the switch component 32a. The sense MOS device 66 has two parasitic diodes D3a and D3b which result from the fabrication process. The parasitic diode D3a of the sense MOS device 66 is formed between the substrate and an isolation layer, e.g. an N-type buried layer (NBL). The parasitic diode D3b of the sense MOS device 66 is formed between the source and drain of the sense MOS device 66.

When the switch component 32a is turned ‘OFF’, there is a large voltage across parasitic diodes D1a and D1b which results in a switch component leakage current i_{lkg_off}=i₁ as described with reference to FIG. 3b. The sense MOS device 66 has a leakage current i₂ due to a large voltage across parasitic diodes D3a and D3b. The leakage current i₂ of the sense MOS device 66 is amplified by the current amplifier 38b and applied as a compensation current ˜i₁=N*i₂ to the node 35 to roughly compensate for the leakage current i_{lkg_off} from the switch component 32a.

When the switch component 32a is turned ‘ON’, there is a large voltage across parasitic diodes D1a and D2a which results in a switch component leakage current i_{lkg_on}=i₁ as described with reference to FIG. 3a. The sense MOS device 66 has a leakage current i₂ due to a large voltage across parasitic diodes D3a and D3b. The leakage current i₂ of the sense MOS device 66 is amplified by the current amplifier 38b and applied as a compensation current ˜i₁=N*i₂ to the drain of the switch component 32a to roughly compensate for the leakage current i_{lkg_on} from the switch component 32a.

The sense MOS device 66 when used as the sense device 36b in the compensation circuit 34 provides unidirectional leakage compensation to the switch component 32a. The sense device 36b has a sense device leakage current defined by parasitic diodes D3a, D3b of sense MOS device 66. The sense MOS device 66 a simpler and more area efficient implementation than the use of a scaled replica of the MOS device 36a (as shown in FIGS. 6 and 7), although it is less accurate.

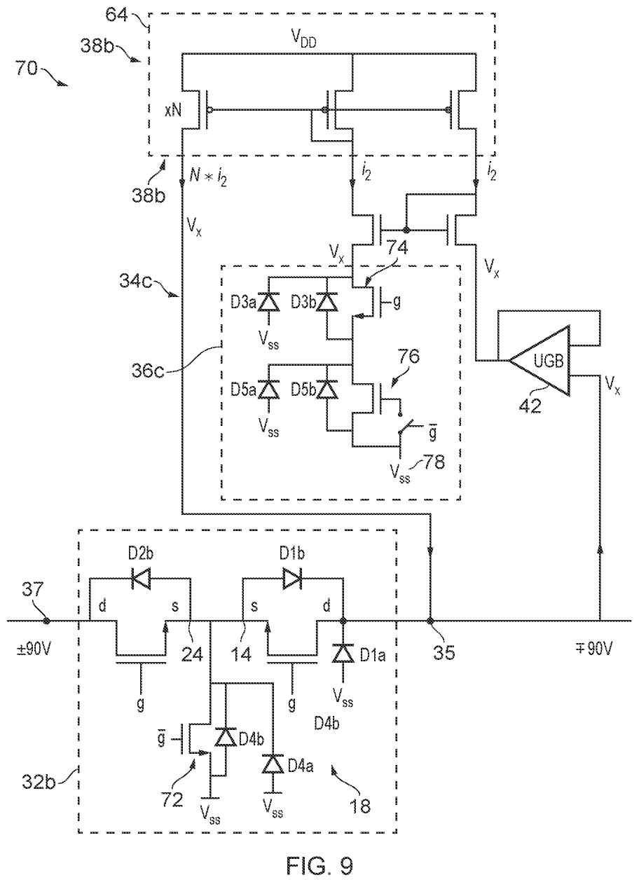

Advantageously, the sense device 36b is coupled to Vss at an anode, therefore the input and output of the compensation circuit is coupled to a node 35 coupled to a first drain of the switch component 32a. This allows for a single compensation circuit to be coupled to an output of many switch components arranged as a many-to-one multiplexor, and provide a compensation current for each of the many switch components. This advantage also applies to other sense devices 36c-e as described with reference to FIGS. 9-11.

FIG. 9 shows a solid state switch device 70 which is an example of the solid state switch device 30 of FIG. 5. Some of the components in FIG. 9 are similar to components in FIG. 8 and use the same reference numbers. For purposes of conciseness, similar components will not be described in detail again. In contrast to the solid state switch device 60, solid state switch device 70 shows an alternative sense device 36c and switch component 32b which is advantageous for use when a switch component 32b may be configured to be bi-directional. To provide a bi-directional compensation, a second compensation circuit similar to the compensation circuit 34c may be provided at the left side of 32b to provide an output (e.g., a compensation current approximately equal to a leakage current of the switch component 32b) coupled to a node 37 coupled to the second drain of the switch component 32b.

A switch component 32b comprises a NLDMOS switch 18 as shown at FIG. 2 and further comprises a pull-down MOS device 72 coupled to the source terminals 14, 24 of the first and second NLDMOS 10, 20. The switch component 32b has a switch component leakage current defined by parasitic diodes D1a, D1b, D4a, and D4b. The pull-down MOS device 72 is arranged to pull the voltage Vmid at the source terminals 14, 24 of the first and second NLDMOS 10, 20 to Vss (or reference voltage) when the switch component 32b is turned OFF′. The addition of the pull-down MOS device 72 may enable efficient bi-directional operation of the switch component 32b. Thus, when the switch component 32b is turned ‘OFF’, the pull-down MOS device 72 is turned ‘ON’. When the switch component 32b is turned ‘ON’ the pull-down MOS device 72 contributes to the leakage current i₁ of the switch component 32b due to a large voltage across parasitic diodes D4a and D4b. The pull-down MOS device 72 may be smaller than a MOS device of the NLDMOS switch 18 to reduce area and leakage.

To compensate for the switch component leakage current i₁ contributed by the NLDMOS switch 18 and the pull-down MOS device 72, the sense device 36c may comprise a first sense MOS device 74 and a second sense MOS device 76. The sense device 36c has a sense device leakage current defined by parasitic diodes D3a, D3b, D5a, D5b. The sense device 36c device is coupled to Vss (or reference voltage) via a control switch 78. The control switch 78 is configured to be open when the switch component 32b is closed (i.e., ‘ON’).

The first sense MOS device 74 has: a drain terminal coupled to the first current mirror 62 of the current mirror arrangement; a source terminal coupled to the drain of the second sense MOS device 76; and a gate terminal coupled to a gate driver circuit such that the gate of the first sense MOS device 74 receives a signal received at the gate(s) of the switch component 32b. The second sense MOS device 76 has: a drain terminal coupled to the source terminal of the first sense MOS device 74; a source terminal coupled to Vss; and a gate terminal arranged to couple to Vss when the switch component 32b is ‘OFF’, and arranged to float when the switch component is ‘ON’. The first sense MOS device 74 is N times smaller than one of the MOS devices (e.g., LDMOS 10) of the switch component 32b. The second sense MOS device 74 is N times smaller than the pull-down MOS device 72. The first sense MOS device 74 has two parasitic diodes D3a and D3b which result from the fabrication process. The second sense MOS device 76 has two parasitic diodes D5a and D5b which result from the fabrication process. The parasitic diodes D3a, D5a of the first and second sense MOS device 74, 76 are formed between the substrate and an isolation layer, e.g. an N-type buried layer (NBL). The parasitic diodes D3b, D5b are formed between the source and drain of the first and second sense MOS devices 74, 76.

When the switch component 32b is turned ‘OFF’, there is a large voltage across parasitic diodes D1a and D1b which results in a switch component leakage current i_{lkg}_{_{off}}=i₁. The first sense MOS device 74 has a leakage current i₂ due to a large voltage across parasitic diodes D3a and D3b. Note that second sense device 76 is turned ‘ON’ which results in its parasitic diodes D5a and D5b being bypassed. The leakage current i₂ is amplified by the current amplifier 38b and applied as a compensation current ˜i₁=N*i₂ to the node 35 coupled to the first drain of the switch component 32b to roughly compensate for the leakage current i_{lkg_off} from the switch component 32b.

When the switch component 32b is turned ‘ON’, there is a large voltage across parasitic diodes D1a, D4a, and D4b which results in a switch component leakage current i_{lkg_on}=i₁. The first sense MOS device 74 in combination with the second sense MOS device 76 has a leakage current i₂ due to a large voltage across parasitic diodes D3a, D5a, and D5b. The leakage current i₂ is amplified by the current amplifier 38b and applied as a compensation current ˜i₁=N*i₂ to the node 35 to roughly compensate for the leakage current i_{lkg_on} from the switch component 32b.

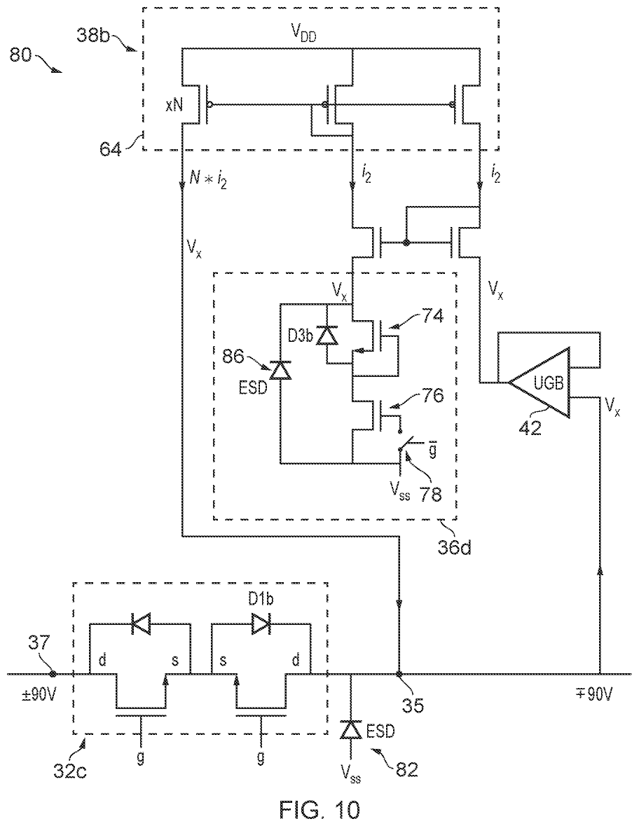

FIG. 10 shows a solid state switch device 80 which is an example of the solid state switch device 30 of FIG. 5. Some of the components in FIG. 10 are similar to components in FIG. 8 and use the same reference numbers. For purposes of conciseness, similar components will not be described in detail again. In contrast to the solid state switch device 60, solid state switch device 80 shows an alternative sense device 36d and an alternative switch component 32c.

The switch component 32c may be manufactured with silicon-on-insulator (SOI) techniques, e.g., a buried oxide isolated device. A SOI switch component 32c does not have a parasitic diode between the substrate and an isolation layer. The SOI switch component 32c comprises a first drain terminal coupled to a node 35 and a second drain terminal coupled to a node 37. The SOI switch component 32c may further comprise an electrostatic discharge (ESD) diode 82 coupled to the node 35 of the switch component 32c.

The sense device 36d comprises a first sense MOS device 74, a second sense MOS device 76, and control switch 78 corresponding to the arrangement shown in FIG. 9. The sense device 36d further comprises a sense ESD diode 86 which is N times smaller than the ESD diode 82 of the switch component 32c. The sense device 36d has a sense device leakage current defined by parasitic diode D3b and sense ESD diode 86. The sense ESD diode 86 is arranged such that its anode is coupled to Vss and its cathode is coupled to the current amplifier 38b via the first current mirror 62 of the current mirror arrangement as shown.

When the switch component 32c is ‘OFF’ then the main source of leakage is through the reverse biased ESD diode 82 to Vss and through parasitic diode D1b of the switch component 32c, which results in a leakage current i_{lkg_off}=i₁. The main source of leakage through the sense device 36d is through parasitic diode D3b and sense ESD diode 86, which results in a leakage current i₂. There may be other sources of leakage in the sense device 32c but these are negligible if for example the scale of second sense MOS device 76 is much less than the first sense MOS device 74.

When the switch component 32c is ‘ON’ the main source of leakage is through the reverse biased ESD diode 82 to Vss, which results in a switch component leakage current i_{lkg_on}=i₁. The main source of leakage through the sense device 36d is through the sense ESD diode 86, which results in a leakage current i₂. The leakage current i₂ is amplified by the current amplifier 38b and applied as a compensation current ˜i₁=N*i₂ to the node 35 to roughly compensate for the leakage current i_{lkg_on} from the switch component 32c.

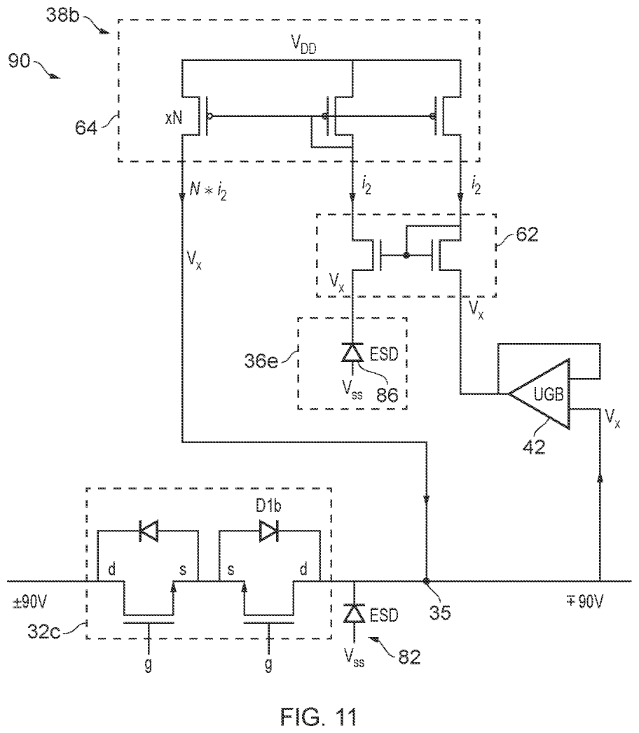

FIG. 11 shows a solid state switch device 90 which is an example of the solid state switch device 30 of FIG. 5. Some of the components in FIG. 11 are similar to components in FIG. 10 and use the same reference numbers. For purposes of conciseness, similar components will not be described in detail again. In contrast to the solid state switch device 80, solid state switch device 90 shows an alternative sense device 36e.

The sense device 36e is a sense ESD diode 86 which is N times smaller than the ESD diode 82 of the switch component 32c. The sense device 36e has a sense device leakage current defined by sense ESD diode 86. The sense ESD diode 86 is arranged such that its anode is coupled to Vss and its cathode is coupled to the current amplifier 38b via the first current mirror 62 of the current mirror arrangement as shown.

When the switch component 32c is ‘OFF’ then the main source of leakage is through the reverse biased ESD diode 82 to Vss and through parasitic diode D1b of the switch component 32c, which results in a switch component leakage current i_{lkg_off}=i₁. The main source of leakage through the sense device 36d is through the sense ESD diode 86, which results in a leakage current i₂. There may be other sources of leakage in the sense device 32c but these are neglected for simplicity. The sense leakage current i₂ is amplified by the current amplifier 38b and applied as a compensation current ˜i₁=N*i₂ to the node 35 to roughly compensate for the leakage current i_{lkg_off} from the switch component 32c.

When the switch component 32c is ‘ON’ the main source of leakage is through the reverse biased ESD diode 82 to Vss, which results in a switch component leakage current i_{lkg_on}=i₁. The main source of leakage through the sense device 36d is through the sense ESD diode 86, which results in a leakage current i₂. The leakage current i₂ is amplified by the current amplifier 38b and applied as a compensation current ˜i₁=N*i₂ to the node 35 to roughly compensate for the leakage current i_{lkg_on} from the switch component 32a.

Alternatively, the sense device 36e may be a BJT (or other semiconductor device) arranged to be functionally similar to the sense ESD diode 86. In addition, a diode may be added in parallel with the sense ESD diode 86 with a suitable switching arrangement to compensate for the leakage through parasitic diode D1b when the switch component 32c is ‘OFF’.

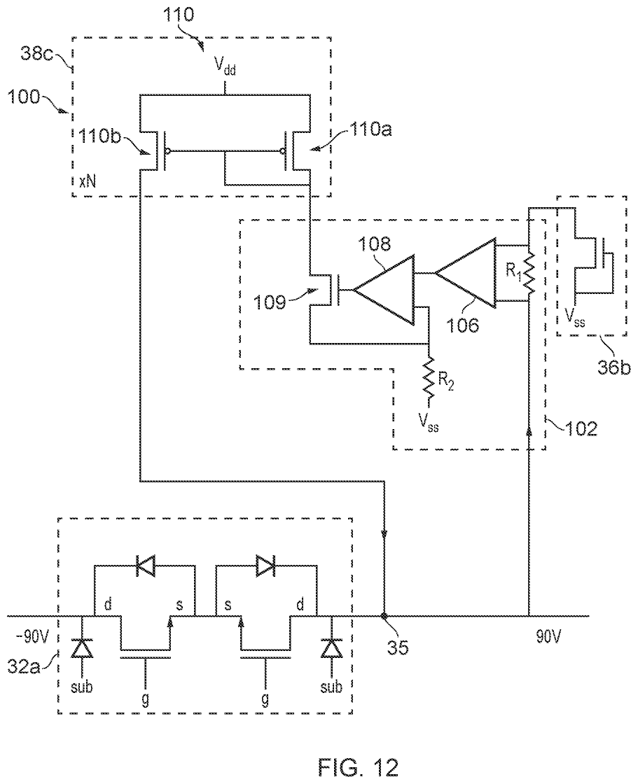

FIG. 12 shows a solid state switch device 100 which is an example of the solid state switch device 30 of FIG. 5. Some of the components in FIG. 12 are similar to components in FIG. 8 and use the same reference numbers. For purposes of conciseness, similar components will not be described in detail again. In contrast to the solid state switch device 60, solid state switch device 100 shows an alternative current amplifier 38c, and further comprises a buffer circuit 102.

A node 35 which leakage compensation is desired on is provided to an input of the buffer circuit 102. The buffer circuit 102 comprises an instrumentation amplifier 106, a first resistor R1, an error amplifier 108, a second resistor R2, and an error MOS device 109. The first resistor R1 is arranged between first and second inputs of the instrumentation amplifier 106 such that a voltage drop between the first and second inputs of the instrumentation amplifier 106 represents the current leakage of a sense device 36b. The first input of the instrumentation amplifier 106 is coupled to the node 35, and the second input of the instrumentation amplifier 106 is coupled to the sense device 36b. The output of the instrumentation amplifier 106 is a voltage proportional to the voltage drop over the first and second inputs of the instrumentation amplifier 106. The output voltage of the instrumentation amplifier 106 is converted to a current by a transconductance amplifier which may be realised by the arrangement of the error amplifier 108, second resistor R2, and error MOS device 109. This arrangement of the transconductance amplifier may be advantageous because the op-amp driver stage is not necessary since the output of the error amplifier 108 is connected to the gate of the error MOS device 109 in the arrangement shown in FIG. 12.

The output of the buffer circuit 102 is coupled to a first input of the current amplifier 38c (arranged as a current controlled current source), and a first output of the current amplifier 38c is applied to the node 35. The current amplifier 38c may be implemented as shown in solid state switch device 100 by a current mirror 110 comprising: a first transistor device 110a coupled to the output of the buffer circuit 102 (i.e., the drain of the error MOS device 109); and a second transistor device 110b coupled to the node 35, wherein the second transistor device 110b has a first scale (i.e., N) greater than a second scale of the first transistor device 110a.

Optionally, additional transistor devices may be added as protection devices. For example, transistor device of the current mirror 110 may comprise: a corresponding transistor device in series; and a gate coupled to a fixed voltage reference voltage below Vdd.

In operation, a voltage Vx measured over the first resistor results in a current corresponding to the leakage current i₂ of the sense device being drawn through the error MOS device 109. The amplification of the current is achieved by the current mirror 110 and specifically by scaling the second transistor device 110b (directly coupled to the node 35 coupled to the second drain of the switch component 32a) by a scale factor ratio of N:1 in comparison to the first transistor device 110a. Therefore, the N-scaled transistor device 110b generates a compensation current ˜i₁ roughly equal to N*i₂ to the node 35. In some examples the first and second resistors R1, R2 may have equal resistances.

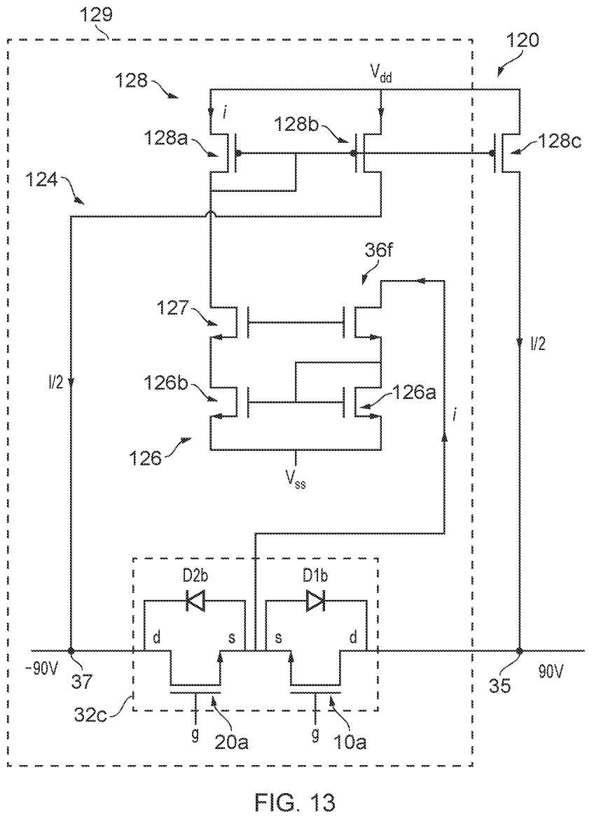

FIG. 13 shows an example of another solid state switch device 120. The solid state switch device 120 comprises a silicon-on-insulator (SOI) switch component 32c (i.e., a fully isolated device). The switch component 32c is described at FIG. 10. The switch component comprises a first MOS device 10a and a second MOS device 20a. The source terminal of the first MOS device 10a is coupled to the source terminal of the second MOS device 20a defining a mid-point.

The solid state switch device 120 comprises a compensation circuit 124 with an input coupled to the mid-point and two outputs coupled to each drain terminal of the first and second MOS devices 10a, 20a of the switch component 32c. Due to the dielectric isolation of the SOI switch component 32c, the leakage can be captured and directed as an input to a current mirror and mirrored and used to provide a compensation current. The compensation circuit 124 comprises a sense device 36f coupled to the mid-point and arranged to pass a leakage current i of the switch component 32c to Vss (i.e., a reference voltage).

When the switch component 32c is ‘ON’, the source and drain terminals of the first and second MOS devices 10a, 20a will be at the same voltage. For a SOI switch component 32c this results in no leakage because the body diodes D1b, D2b have 0V across them. If there is no leakage, then the compensation circuit 124 may be disabled or taken out of the circuit.

When the switch component 32c is ‘OFF’, the common source of the first and second MOS devices 10a, 20a may be pulled to Vss. Therefore, the body diodes D1b, D2b will leak current to Vss. The compensation circuit 124 will capture the current leakage (because the switch component 32c is a SOI device) and can generate two compensation currents i/2 to provide to the drain terminals of the first and second transistor devices 10a, 20a respectively. That is, a first compensation current i/2 is provided to a node 35 coupled to the drain terminal of the first transistor device 10a, and a second compensation current is provided to a node 37 coupled to the drain terminal of the second transistor device 10b. The first compensation current i/2 and the second compensation current i/2 are each approximately half of the leakage current i.

The current mirror arrangement shown in FIG. 13 comprises a first current mirror 126 which may be configured as a current amplifier. A first transistor device 126a of the first current mirror 126 is arranged to pass the leakage current i from the sense device 36f to Vss. The second transistor device 126b is arranged to source a corresponding sense current i to Vss. An optional transistor device 127 may be provided in the current path of the second transistor device 126b to replicate the current path through the sense transistor device 36f.

A second current mirror 128 is provided to replicate and scale the corresponding sense current i passing through a first transistor device 128a. The second current mirror 128 further comprises a second transistor device 128b and a third transistor device 128c which are each arranged to source a compensation current i/2 equal to half of the corresponding sense current i. The first transistor device 128a of the second current mirror 128 is coupled to Vdd and in the current path of the second transistor device 126b of the first current mirror 126, such that the corresponding sense current i passes from Vdd to Vss. The second transistor device 128b of the second current mirror 128 is arranged to source a compensation current i/2 and provide it to node 37 coupled to the drain terminal of the second transistor device 20a. The third transistor device 128c of the second current mirror 128 is arranged to source a compensation current i/2 and provide it the node 35 coupled to the drain terminal of the first transistor device 10a.

Alternatively, the solid state switch device may be defined by the circuit within box 129. That is the circuit within box 129 is functionally identical to the solid state switch device 120 except the second current mirror 128 comprises only the first transistor and the second transistor device 128b. The second transistor device 128b may be scaled to source a compensation current. The compensation current may be equal to half of the corresponding sense current i, or any other ratio of the sense current (including a 1:1 ratio). Thus, providing unidirectional compensation to the node 37.

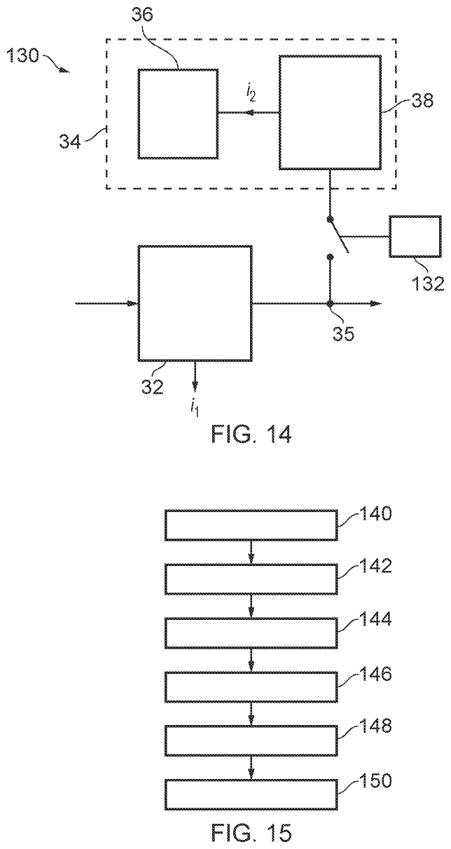

FIG. 14 shows a solid state switch device 130 which is an example of the solid state switch device 30 of FIG. 5. Some of the components in FIG. 14 are similar to components in FIG. 5 and use the same reference numbers. For purposes of conciseness, similar components will not be described in detail again. In contrast to the solid state switch device 30, solid state switch device 130 further comprises a temperature sensor 132 configured to activate the compensation circuit upon sensing a temperature above a temperature threshold. Current leakage increases as temperature increases, therefore, it may be desirable to activate the compensation circuit when the temperature reaches a temperature threshold.

FIG. 15 shows a flow diagram of a method of operating the solid state switch device of FIGS. 5 to 14, to compensate for a switch component leakage current of a switch component 32.

At optional step 140, the temperature sensor 132 senses an activation temperature above a temperature threshold.

In response to sensing the activation temperature, the compensation circuit 34 at the step 142 determines a voltage level at an output of the switch component 32.

At step 144, the compensation circuit 34 applies the voltage level (i.e., a voltage at the voltage level) to a sense device 36.

At step 146, the current amplifier 38 determines a sense device current leakage of the sense device.

At step 148, the current amplifier 38 generates an estimated switch component leakage current ˜i₁ based on the sense device leakage current i₂.

At step 150, the current amplifier 38 outputting the estimated switch component leakage current ˜i₁ to the output of the switch component 35 in order to compensate for the switch component leakage current.

Optionally, the estimated switch component leakage current ˜i₁ is a multiple (e.g., N) of the sense device leakage current i₂, i.e., N*i₂=˜i₁.

Optionally, the buffer 42 is a unitary gain buffer (UGB) 42 (e.g., an operational amplifier based buffer circuit with unitary gain). A UGB 42 provides a low impedance output and therefore can sink or source current at the output 42 of the UGB 42. A UGB 42 can beneficially provide a particularly low difference between the input and output voltages. Therefore, a UGB 42 can achieve improved accuracy of component current measurements due to low current leakage ‘seen’ by the components connected via the solid state switch device. Additionally, if the buffer 42 (and optionally, gate drive circuitry configured to operate the gates of the first NLDMOS 10 and the second MOSFET 40 each) comprises an operational amplifier, then improved THD can be achieved.

The compensation circuit shown in solid state switch device 60, 70, 80, 90, 100 (with its input and output coupled to a node 35 coupled to the first drain of the switch component 32, 32a, 32b, 32c) does not enable compensation in both directions. To enable bi-directional compensation a second compensation circuit substantially similar to the compensation circuit shown in solid state switch device 60, 70, 80, 90, 100 may to be present. Specifically, the second compensation circuit would need to have its input and output coupled to a node 37 coupled to the second drain of the switch component 32, 32a, 32b, 32c. In addition, the compensation circuits need not be the same and may vary in their construction depending on desired area efficiency and accuracy.

Alternatively, the switch component 32, 32a, 32b, 32c may be used in combination with any sense device (including any sense device disclosed herein) and/or any current amplifier (including any current amplifier disclosed herein) in order to realise solid state switch device 30 of FIG. 5.

Alternatively, the current amplifier 38, 38a, 38b, 38c may be used in combination with any sense device (including any sense device disclosed herein) and/or any switch component (including any switch component disclosed herein) in order to realise solid state switch device 30 of FIG. 5. The current amplifier 38 may be implemented as a current mirror arrangement comprising MOS devices 62a, 62b, 64a, 64b, and 64c, however, the current amplifier 38 may be implemented using any arrangement shown described as a current amplifier herein, such as an op-amp 52 etc.

Alternatively, the sense device 36, 36a-36e may be used in combination with any current amplifier (including any current amplifier disclosed herein) and/or any switch component (including any switch component disclosed herein) in order to realise solid state switch device 30 of FIG. 5.

Protection devices as described above at FIGS. 8 and 12 may be applied to other solid state switch device examples disclosed herein, or different protection devices/protection circuits may be used in the solid state switch devices of any example. The transistor devices of the current mirrors disclosed herein may be MOS devices or any type of suitable semiconductor device.

The values of any components herein may be changed depending on the application and/or designer choice.

For all of the above designs and circuits, it is possible to add additional components while still achieving the technical effects associated with each embodiment.

In FIGS. 1-13, there are shown n-type devices (and p-type devices). However, the teachings can also be readily applied to p-type devices (and n-type devices) by a person skilled in the art, and vice versa.

When a MOSFET is an n-type MOSFET, it may comprise a buried layer which is an NBL. Alternatively, when a MOSFET is an p-type MOSFET, it may comprise a buried layer which is a p-type buried layer (PBL). The term buried layer may be used herein for n or p-type high-voltage MOSs. The term isolation layer may be used herein for n or p-type MOSs.

When reference is made to a drain, source, gate, bulk, buried layer, isolation layer or other input/output of a component, this may include a drain terminal, source terminal, gate terminal, bulk terminal, buried layer terminal, isolation terminal or other input/output terminal of a component, respectively (and vice versa).

Alternatively, the UGB 42 may be any other type of buffer suitable for the operation of the compensation circuit 34, such as, a voltage follower, or a cascade complementary source follower (CCSF). The CCSF can achieve near zero voltage drop across the CCSF, although, this may vary with temperature and silicon processes. Alternatively, the buffer may be any other implementation of a source follower type circuit or buffer. Optionally, the buffer may comprise an operational amplifier. The operational amplifier may be one of: a continuous time auto-zero operational amplifier; or a continuous time ping-pong auto zero operational amplifier, to achieve a low voltage difference across the UGB 42.

Alternatively, in place of MOS devices, other type of FET devices may be used.

### General

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.”

The words “coupled” or “connected”, as generally used herein, refer to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list.

It is to be understood that one or more features from one or more of the above-described embodiments may be combined with one or more features of one or more other ones of the above-described embodiments, so as to form further embodiments which are within the scope of the appended claims.

1. A solid state switch device, comprising:
a switch component comprising a metal-oxide-semiconductor field-effect transistor, MOSFET, comprising a drain terminal, a source terminal, a gate terminal, and configured to generate a switch component leakage current based on non-idealities of the MOSFET;
a compensation circuit comprising:
a sense device for compensating current leakage of the switch component, and configured to generate a sense device leakage current that is correlated with the switch component leakage current; and
a current amplifier configured to:
generate an estimated switch component leakage current (˜i₁) based on the sense device leakage current (i₂);
output the estimated switch component leakage current to the drain terminal of the MOSFET in order to compensate for the switch component leakage current.

2. The solid state switch device of claim 1, wherein the compensation circuit is configured to:
detect a voltage level at the drain terminal of the MOSFET; and
apply the voltage level to the sense device in order to generate the sense device leakage current correlated with the switch component leakage current.

3. The solid state switch device of claim 1, wherein the MOSFET is a first LDMOS, and the switch component further comprises a second LDMOS comprising: a drain terminal, a source terminal, a gate terminal, wherein the source terminal of the second LDMOS is coupled to the source terminal of the first LDMOS.

4. The solid state switch device of claim 1, wherein the estimated switch component leakage current is a multiple of the sense device leakage current.

5. The solid state switch device of claim 1, wherein the sense device leakage current is correlated with the switch component leakage current such that the sense device leakage current is N times less than the switch component leakage current.

6. The solid state switch device of claim 1, wherein the estimated switch component leakage current is a multiple of the sense device leakage current, wherein the sense device leakage current is correlated with the switch component leakage current such that the sense device leakage current is N times less than the switch component leakage current, wherein the multiple is N.

7. The solid state switch device of claim 1, wherein the MOSFET is a buried oxide isolated device, and the switch component further comprises an electrostatic discharge (ESD) diode, wherein the switch component leakage current is further based on non-idealities of the ESD diode.

8. The solid state switch device of claim, wherein the current amplifier is a current mirror comprising: a first transistor device coupled to the sense device; and a second transistor device coupled to the drain terminal of the MOSFET of the switch component, wherein the second transistor device has a first scale greater than a second scale of the first transistor device.

9. The solid state switch device of claim 8, wherein the second transistor device comprises more transistors than the first transistor device.

10. The solid state switch device of claim 1, wherein the current amplifier comprises an operational amplifier comprising a first output and a second output, wherein the first output sources a first current, wherein the second output sources a second current, wherein the second current is a multiple of the first current, wherein the first output is coupled to the sense device, wherein the second output is coupled to the drain terminal of the MOSFET of the switch component.

11. The solid state switch device of claim 1, wherein the switch component is a first switch component, the MOSFET is a first MOSFET, and the sense device is a second switch component, wherein the second switch component comprises a second MOSFET comprising: a drain terminal, a source terminal, a gate terminal, wherein the sense device leakage current is based on non-idealities of the second MOSFET, wherein the first MOSFET has a first scale greater than a second scale of the second MOSFET.

12. The solid state switch device of claim 1, wherein the sense device comprises a cathode coupled to the current amplifier and an anode coupled to the voltage source supply (Vss).

13. The solid state switch device of claim 1, wherein the sense device is coupled to the voltage source supply, Vss, via a switch, wherein the switch is configured to be open when the switch component is closed.

14. The solid state switch device of claim 1, further comprising a temperature sensor configured to activate the compensation circuit upon sensing a temperature above a temperature threshold.

15. A compensation circuit comprising:
a sense device for leakage compensation of a switch component leakage current of a switch component, and configured to generate a sense device leakage current; and
a current amplifier configured to:
generate an estimated switch component leakage current (˜i₁) based on the sense device leakage current (i₂);
output the estimated switch component leakage current to the switch component in order to compensate for the switch component leakage current.

16. The compensation circuit of claim 15, wherein the estimated switch component leakage current is a multiple of the sense device leakage current.

17. A method of compensating for a switch component leakage current of a switch component, the method comprising:
determining a voltage level at an output of the switch component;
applying the voltage level to a sense device;
determining a sense device leakage current of the sense device that is correlated with the switch component leakage current;
generating an estimated switch component leakage current (˜i₁) based on the sense device leakage current;
outputting the estimated switch component leakage current to the output of the switch component in order to compensate for the switch component leakage current.

18. The method of claim 17, wherein the estimated switch component leakage current is a multiple of the sense device leakage current.

19.-21. (canceled)
